(19) United States
(12) Patent Application Publication
(10) Pub. No.: US 2013/0081858 A1
(43) Pub. Date: Apr. 4, 2013

(54) PHOTOSENSITIVE RESIN COMPOSITION, CURED FILM THEREOF AND PRINTED CIRCUIT BOARD

(71) Applicant: Taiyo Ink MFG. Co. Ltd., Hiki-Gun (JP)

(72) Inventors: Akio Norikoshi, Hiki-Gun (JP); Masao Arima, Hiki-Gun (JP)

(73) Assignee: Taiyo Ink MFG. Co. Ltd., Hiki-Gun (JP)

(21) Appl. No.: 13/630,506

(22) Filed: Sep. 28, 2012

(30) Foreign Application Priority Data
Sep. 30, 2011 (JP) 2011-218748

(51) Int. Cl. G03F 7/004; H05K 1/00

(52) U.S. Cl. 174/250; 430/280.1

(57) ABSTRACT

[Problems] The present invention relates to a photosensitive resin composition in which a cured film obtained therefrom has good resistance to electroless gold plating and occurrence of whitening phenomenon in a solder leveling process (pre-soldering process) and an electroless gold plating process is inhibited; a cured film of the photosensitive resin composition; and a printed circuit board comprising the cured film.

[Means for Solution] The photosensitive resin composition is characterized by comprising (A) a non-photosensitive carboxylic acid resin, (B) an aluminum-containing inorganic filler and (C) an epoxy resin. It is preferred that the photosensitive resin composition further comprise a photosensitive monomer.

### TECHNICAL FIELD

The present invention relates to a photosensitive resin composition, a cured film thereof and a printed circuit board comprising the cured film. More particularly, the present invention relates to a photosensitive resin composition in which a cured film obtained therefrom has good resistance to electroless gold plating and occurrence of whitening phenomenon in a solder leveling process (pre-soldering process) and an electroless gold plating process is inhibited; a cured film of the photosensitive resin composition; and a printed circuit board comprising the cured film.

### BACKGROUND ART

In recent years, as solder resists for consumer and industrial printed circuit boards, from the standpoint of attaining high precision and high density, liquid developing-type solder resists that are, upon being irradiated with UV light, developed to form an image and then subjected to final curing (main curing) by at least either of heating and irradiation with a light have been employed. Further, in response to densification of printed circuit boards associated with miniaturization of electronic devices, a solder resist with improved workability and performance has been demanded.

Among such liquid developing-type solder resist, with consideration of environmental problems, the prevailing trend is to use an alkali developing-type photosolder resist utilizing an aqueous alkaline solution as its developing solution. As such an alkali developing-type photosolder resist, an epoxy acrylate-modified resin derived by modification of an epoxy resin is commonly employed.

For example, Patent Document 1 discloses a solder resist composition which comprises a photosensitive resin obtained by adding an acid anhydride to a reaction product of a novolac-type epoxy compound and an unsaturated monobasic acid, a photopolymerization initiator, a diluent and an epoxy compound. Patent Document 2 discloses a solder resist composition which comprises: a photosensitive resin, which is obtained by adding (meth)acrylic acid to an epoxy resin produced by allowing a reaction product of a salicyl aldehyde and a monohydric phenol to react with epichlorohydrin and further allowing the resultant to react with a polybasic carboxylic acid or an anhydride thereof; a photopolymerization inhibitor; an organic solvent and the like.

Meanwhile, recently, from the standpoint of reducing the environmental stress, more printed circuit boards have been made halogen-free. For example, the JPCA (Japan Electronics Packaging and Circuits Association) Standard (JPCA-ES01) defines a copper-clad laminate which has a chlorine (Cl) content of not higher than 0.09 wt % (900 ppm), a bromine (Br) content of not higher than 0.09 wt % (900 ppm) and a total content of chlorine (Cl) and bromine (Br) of not higher than 0.15 wt % (1,500 ppm) as a halogen-free copper-clad laminate. Therefore, a reduction in the halogen content is demanded also for a solder resist, which is one of the principal components of printed circuit boards.

Among those photosensitive carboxylic acid resins that are contained in a solder resist, ones that are derived from an epoxy resin contain chlorine ion originated from epichlorohydrin; therefore, such photosensitive carboxylic acid resins are not preferred from the standpoint of attaining a halogen-free printed circuit board/solder resist. Accordingly, non-photosensitive carboxylic acid resins of non-epoxy resin origin and resin compositions in which a photosensitive carboxylic acid resin of non-epoxy resin origin is adopted have been examined.

### RELATED ART DOCUMENTS

### Patent Documents

Patent Document 1: Japanese Unexamined Patent Application Publication No. S61-243869 (Claims)
Patent Document 2: Japanese Unexamined Patent Application Publication No. H3-250012 (Claims)
Patent Document 3: Japanese Unexamined Patent Application Publication No. 2010-237575 (Claims)

### SUMMARY OF THE INVENTION

### Problems to be Solved by the Invention

However, a resin composition in which such a non-photosensitive carboxylic acid resin described in the above is used has a problem in that, when a substrate having a cured film which is obtained from the resin composition and exposed to a light is subjected to a solder leveling process (pre-soldering process) or an electroless gold plating process, the surface of the cured film becomes clouded (hereinafter, referred to as “whitening”) in some cases.

Further, in a resin composition in which a carboxylic acid resin having a relatively high acid value is used in order to ensure good developing property with a dilute alkali, there is also a problem in that, during electroless gold plating, the plating solution may infiltrate into a cured solder resist product and swelling and/or detachment of the cured product may occur.

In view of the above, an object of the present invention is to provide a photosensitive resin composition in which a cured film obtained therefrom has good resistance to electroless gold plating and occurrence of whitening phenomenon in a solder leveling process (pre-soldering process) and an electroless gold plating process is inhibited; a cured film of the photosensitive resin composition; and a printed circuit board comprising the cured film.

### Means for Solving the Problems

The present inventors intensively studied to discover that the above-described problems can be solved by a photosensitive resin composition which comprises a non-photosensitive carboxylic acid resin, an aluminum-containing inorganic filler and an epoxy resin, thereby completing the present invention.

That is, the photosensitive resin composition according to the present invention comprises (A) a non-photosensitive carboxylic acid resin, (B) an aluminum-containing inorganic filler and (C) an epoxy resin.

It is preferred that the photosensitive resin composition according to the present invention further comprise a photosensitive monomer.

Further, in the photosensitive resin composition according to the present invention, it is preferred that the above-described (C) epoxy resin be a bifunctional epoxy resin.

Further, it is preferred that the photosensitive resin composition according to the present invention further comprise a photosensitive carboxylic acid resin. In addition, in the photosensitive resin composition according to the present invention, it is preferred that the content of the photosensitive carboxylic acid resin be in the range of not higher than 90 parts by mass with respect to 100 parts by mass of total carboxylic acid resins.

Further, it is preferred that the photosensitive resin composition according to the present invention have a chlorine content of not higher than 900 ppm.

Further, it is preferred that the photosensitive resin composition according to the present invention be one which is used as a solder resist.

The cured film according to the present invention is obtained by curing any one of the above-described photosensitive resin compositions.

The printed circuit board according to the present invention comprises the above-described cured film.

### Effects of the Invention

By the present invention, a photosensitive resin composition in which a cured film obtained therefrom has good resistance to electroless gold plating and occurrence of whitening phenomenon in a solder leveling process (pre-soldering process) and an electroless gold plating process is inhibited; a cured film of the photosensitive resin composition; and a printed circuit board comprising the cured film can be provided. Further, the photosensitive resin composition according to the present invention is suitably used as a permanent coating film of a printed circuit board and in particular, it is suitably used as a solder resist material and an interlayer insulation material.

### MODE FOR CARRYING OUT THE INVENTION

The photosensitive resin composition according to the present invention is characterized by comprising (A) a non-photosensitive carboxylic acid resin, (B) an aluminum-containing inorganic filler and (C) an epoxy resin. As described later, since the (A) non-photosensitive carboxylic acid resin is not derived from an epoxy resin, it contains a small amount of chlorine ions originated from epichlorohydrin. Therefore, by using this (A) non-photosensitive carboxylic acid resin, the halogen content in the photosensitive resin composition as a whole can be reduced. From the standpoint of halogen-free property, it is preferred that the photosensitive resin composition according to the present invention have a chlorine content of not higher than 900 ppm.

By allowing the photosensitive resin composition to contain the (B) aluminum-containing inorganic filler, occurrence of whitening phenomenon can be inhibited.

These components will now each be described in detail.

### [(A) Non-photosensitive Carboxylic Acid Resin]

The above-described (A) non-photosensitive carboxylic acid resin is a resin which has a carboxyl group in the molecule but does not have a photosensitive group such as an ethylenically unsaturated bond.

Specific examples of such non-photosensitive carboxylic acid resin include the following compounds (that each may be either an oligomer or a polymer):

Non-photosensitive carboxylic acid resins obtained by copolymerization of an unsaturated carboxylic acid such (meth)acrylic acid and an unsaturated group-containing compound such as styrene, α-methylstyrene, lower alkyl (meth)acrylate or isobutylene. Here, the term “lower alkyl” refers to an alkyl group having 1 to 5 carbon atoms.

The (A) non-photosensitive carboxylic acid resin used in the present invention has an acid value of preferably not less than 120 mg KOH/g, more preferably 140 to 180 mg KOH/g. When the acid value of the (A) non-photosensitive carboxylic acid resin is less than 120 mg KOH/g, development of the photosensitive resin composition with an alkali may become difficult.

The weight-average molecular weight of the (A) non-photosensitive carboxylic acid resin used in the present invention varies depending on the resin skeleton; however, in general, it is preferably 10,000 to 30,000. When the weight-average molecular weight is less than 10,000, the dryness to touch (tack-free performance) may be poor and the moisture resistance of the resulting coating film after exposure to a light may be deteriorated to cause a reduction in the film at the time of development, which may greatly impair the resolution. On the other hand, when the weight-average molecular weight is greater than 30,000, the developing property may be markedly deteriorated and the storage stability may be impaired. The weight average molecular weight of the (A) non-photosensitive carboxylic acid resin is more preferably 10,000 to 25,000.

It is preferred that the content of the (A) non-photosensitive carboxylic acid resin be 10 to 100 parts by mass with respect to 100 parts by mass of total carboxylic acid resins. When the content is less than 10 parts by mass, the dryness to touch (tack-free performance) is deteriorated. The content is more preferably 20 to 50 parts by mass.

It is noted here that the term “total carboxylic acid resins” means a sum of the (A) non-photosensitive carboxylic acid resin and the later-described photosensitive carboxylic acid resin.

### [(B) Aluminum-containing Inorganic Filler]

The photosensitive resin composition according to the present invention further comprises (B) an aluminum-containing inorganic filler.

Since the (B) aluminum-containing inorganic filler has a refractive index similar to that of the resins to be used, it is thought that the use of the (B) aluminum-containing inorganic filler makes it difficult for whitening of gold plating and solder leveler to occur. Further, since the shrinkage of the resulting coating film on curing is also reduced, it is believed that the resistance to gold plating is improved. Further, when a filler having a large specific gravity such as barium sulfate (specific gravity: 4.5) is used, residues of the filler may be observed on copper at the time of development; however, it was confirmed that, since the (B) aluminum-containing inorganic filler has a small specific gravity and is not likely to aggregate in the lower part of the coating film, the (B) aluminum-containing inorganic filler prevents a filler residue from remaining on copper at the time of development.

In addition, it was confirmed that, since the (B) aluminum-containing inorganic filler has a small specific gravity as described in the above, even when the (B) aluminum-containing inorganic filler is added to a composition in a large amount, the composition has superior coating area efficiency as compared to a composition containing a filler having a large specific gravity. Here, in photosensitive resin compositions, solder resist inks generally have a specific gravity in the range of 1.3 to 1.5. When the specific gravity is larger than 1.5, the coating area efficiency is impaired and the ink is thus uneconomical; therefore, a solder resist ink having such a specific gravity is not preferred. Accordingly, it is preferred that the specific gravity of the ink be adjusted to be in the above-described range mainly by changing the amount of the (B) aluminum-containing inorganic filler.

The above-described (B) aluminum-containing inorganic filler is an inorganic filler which contains aluminum, preferably an aluminum-containing mineral. As the aluminum-containing inorganic filler, any known aluminum-containing inorganic filler can be used. Specific examples thereof include kaolin, Neuburg siliceous earth and aluminum hydroxide. The content of the aluminum-containing inorganic filler is preferably 50 to 500 parts by mass, more preferably 100 to 400 parts by mass, with respect to 100 parts by mass of total carboxylic acid resins.

Kaolin is a hydrated aluminum silicate having a laminated structure. It preferably has a composition represented by the chemical formula, (OH)₈Si₄Al₄O₁₀ or Al₂O₃.2SiO₂.2H₂O. In general, there are three types of naturally occurring kaolin (kaolinite, dickite and nacrite), all of which can be used. The particle size thereof is not particularly restricted and kaolin of any particle size may be used. Further, kaolin whose surface is treated with a silane coupling agent or the like can also be used.

Examples of kaolin include SPESWHITE, STOCKLITE, DEVOLITE and POLWHITE, which are manufactured by Imerys Minerals Japan K.K.; KAOFINE 90, KAOBRITE 90, KAOGLOSS 90, KAOFINE, KAOBRITE and KAOGLOSS (trade names), which are manufactured by Shiraishi Calcium Kaisha, Ltd. (THIELE); UNION CLAY RC-1 manufactured by Takehara Kagaku Kogyo Co., Ltd.; and HUBER 35, HUBER 35B, HUBER 80, HUBER 80B, HUBER 90, HUBER 90B, HUBER HG90, HUBER TEK2001, POLYGLOSS 90 and LITHOSPERSE 7005CS, which are manufactured by manufactured by J. M. Huber Corporation.

Neuburg siliceous earth particles are naturally occurring bound substances called “sillitin” or “sillikolloid” and have a structure in which spherical silica and plate-form kaolinite are loosely bound with each other.

Examples of Neuburg siliceous earth particles include SILLITIN V85, SILLITIN V88, SILLITIN N82, SILLITIN N85, SILLITIN N87, SILLITIN Z86, SILLITIN Z89, SILLIKOLLOID P87, SILLITIN N85 PURISS, SILLITIN Z86 PURISS, SILLITIN Z89 PURISS and SILLIKOLLOID P87 PURISS (all of which are trade names; manufactured by Hoffmann Mineral GmbH). These may be used individually, or two or more thereof may be used in combination.

Examples of surface-treated Neuburg siliceous earth particles include AKTISIL VM56, AKTISIL MAM, AKTISIL MAM-R, AKTISIL EM, AKTISIL AM, AKTISIL MM and AKTISIL PF777 (all of which are trade names; manufactured by Hoffmann Mineral GmbH). These may be used individually, or two or more thereof may be used in combination.

As aluminum hydroxide, any commercially available product can be used. Examples thereof include HIGILITE Series (H-21, H-31, H-32, H-42, H-42M, H-43 and H-43M) (manufactured by Showa Denko K.K.).

The photosensitive resin composition according to the present invention may further comprise, as required, a filler other than the aluminum-containing inorganic filler. As such a filler, a known inorganic or organic filler can be used, and examples thereof include barium sulfate, spherical silica and talc. Further, in order to attain white outer appearance and flame retardancy, a metal oxide such as titanium oxide or a metal hydroxide may also be used as an extender filler.

### [(C) Epoxy Resin]

The above-described epoxy resin is a resin having an epoxy group and any known epoxy resin can be used. Examples thereof include bifunctional epoxy resins having two epoxy groups in one molecule and multifunctional epoxy resins having a plurality of epoxy groups in one molecule; however, from the standpoint of potential contribution to an improvement in the resistance to gold plating, bifunctional epoxy resins are preferred and preferred thereamong is a bifunctional epoxy resin which is in a liquid state at room temperature (25° C.).

Examples of the above-described multifunctional epoxy compound include bisphenol A-type epoxy resins such as jER828, jER834, jER1001 and jER1004, which are manufactured by Mitsubishi Chemical Corporation, EPICLON 840, EPICLON 850, EPICLON 1050 and EPICLON 2055, which are manufactured by DIC Corporation, EPOTOHTO YD-011, YD-013, YD-127 and YD-128, which are manufactured by Tohto Kasei Co., Ltd., D.E.R.317, D.E.R.331, D.E.R.661 and D.E.R.664, which are manufactured by The Dow Chemical Company, ARALDITE 6071, ARALDITE 6084, ARALDITE GY250 and ARALDITE GY260, which are manufactured by BASF Japan Ltd., SUMI-EPDXY ESA-011, ESA-014, ELA-115 and ELA-128, which are manufactured by Sumitomo Chemical Co., Ltd., and A.E.R.330, A.E.R.331, A.E.R.661 and A.E.R.664, which are manufactured by Asahi Chemical Industry Co., Ltd. (all of the above are trade names); brominated epoxy resins such as jERYL 903 manufactured by Mitsubishi Chemical Corporation, EPICLON 152 and EPICLON 165, which are manufactured by DIC Corporation, EPOTOHTO YDB-400 and YDB-500, which are manufactured by Tohto Kasei Co., Ltd., D.E.R.542 manufactured by The Dow Chemical Company, ARALDITE 8011 manufactured by BASF Japan Ltd., SUMI-EPDXY ESB-400 and ESB-700, which are manufactured by Sumitomo Chemical Co., Ltd., and A.E.R.711 and A.E.R.714, which are manufactured by Asahi Chemical Industry Co., Ltd. (all of the above are trade names); novolac-type epoxy resins such as jER152 and jER154, which are manufactured by Mitsubishi Chemical Corporation, D.E.N.431 and D.E.N.438, which are manufactured by The Dow Chemical Company, EPICLON N-730, EPICLON N-770 and EPICLON N-865, which are manufactured by DIC Corporation, EPOTOHTO YDCN-701 and YDCN-704, which are manufactured by Tohto Kasei Co., Ltd., ARALDITE ECN1235, ARALDITE ECN1273, ARALDITE ECN1299 and ARALDITE XPY307, which are manufactured by BASF Japan Ltd., EPPN-201, EOCN-1025, EOCN-1020, EOCN-104S, RE-306 and NC-3000, which are manufactured by Nippon Kayaku Co., Ltd., SUMI-EPDXY ESCN-195X and ESCN-220, which are manufactured by Sumitomo Chemical Co., Ltd., A.E.R.ECN-235 and ECN-299, which are manufactured by Asahi Chemical Industry Co., Ltd., YDCN-700-2, YDCN-700-3, YDCN-700-5, YDCN-700-7, YDCN-700-10, YDCN-704 and YDCN-704A, which are manufactured by Nippon Steel Chemical Co., Ltd., and EPICLON N-680, N-690 and N-695, which are manufactured by DIC Corporation (all of the above are trade names); bisphenol F-type epoxy resins such as EPICLON 830 manufactured by DIC Corporation, jER807 manufactured by Mitsubishi Chemical Corporation, EPOTOHTO YDF-170, YDF-175 and YDF-2004, which are manufactured by Tohto Kasei Co., Ltd., and ARALDITE XPY306 manufactured by BASF Japan Ltd. (all of the above are trade names); hydrogenated bisphenol A-type epoxy resins such as EPOTOHTO ST-2004, ST-2007 and ST-3000 (trade names) which are manufactured by Tohto Kasei Co., Ltd.; glycidyl amine-type epoxy resins such as jER604 manufactured by Mitsubishi Chemical Corporation, EPOTOHTO YH-434 manufactured by Tohto Kasei Co., Ltd., ARALDITE MY720 manufactured by BASF Japan Ltd. and SUMI-EPDXY ELM-120 manufactured by Sumitomo Chemical Co., Ltd. (all of the above are trade names); hydantoin-type epoxy resins such as ARALDITE CY-350™ manufactured by BASF Japan Ltd.; alicyclic epoxy resins such as CELLOXIDE 2021 manufactured by Daicel Corporation, and ARALDITE CY175 and CY179, which are manufactured by BASF Japan Ltd. (all of the above are trade names); trihydroxyphenyl methane-type epoxy resins such as YL-933 manufactured by Mitsubishi Chemical Corporation and T.E.N., EPPN-501 and EPPN-502, which are manufactured by The Dow Chemical Company (all of the above are trade names); bixylenol-type or biphenol-type epoxy resins and mixtures thereof, such as YL-6056, YX-4000 and YL-6121 (all of which are trade names) manufactured by Mitsubishi Chemical Corporation; bisphenol S-type epoxy resins such as EBPS-200 manufactured by Nippon Kayaku Co., Ltd., EPX-30 manufactured by ADEKA Corporation and EXA-1514 (trade name) manufactured by DIC Corporation; bisphenol A novolac-type epoxy resins such as jER157S (trade name) manufactured by Mitsubishi Chemical Corporation; tetraphenylolethane-type epoxy resins such as jERYL-931 manufactured by Mitsubishi Chemical Corporation and ARALDITE 163 manufactured by BASF Japan Ltd. (both of which are trade names); heterocyclic epoxy resins such as ARALDITE PT810 manufactured by BASF Japan Ltd. and TEPIC manufactured by Nissan Chemical Industries, Ltd. (both of which are trade names); diglycidyl phthalate resins such as BLEMMER DGT manufactured by NOF Corporation; tetraglycidyl xylenoylethane resins such as ZX-1063 manufactured by Tohto Kasei Co., Ltd.; naphthalene group-containing epoxy resins such as ESN-190 and ESN-360, which are manufactured by Nippon Steel Chemical Co., Ltd., and HP-4032, EXA-4750 and EXA-4700, which are manufactured by DIC Corporation; epoxy resins having a dicyclopentadiene skeleton, such as HP-7200 and HP-7200H manufactured by DIC Corporation; glycidyl methacrylate copolymer-based epoxy resins such as CP-50S and CP-50M manufactured by NOF Corporation; cyclohexylmaleimide-glycidyl methacrylate copolymer epoxy resins; and CTBN-modified epoxy resins (for example, YR-102 and YR-450 manufactured by Tohto Kasei Co., Ltd.). However, the multifunctional epoxy compound is not restricted to these resins. Thereamong, in particular, novolac-type epoxy resins such as cresol novolac-type epoxy resins, heterocyclic epoxy resins, bixylenol-type epoxy resins and mixtures thereof are preferred.

The above-described bifunctional epoxy resin is a compound having two epoxy groups in the molecule, preferably one which is in a liquid state at room temperature (25° C.). Examples of the bifunctional epoxy resin include bisphenol A-type epoxy resins, hydrogenated bisphenol A-type epoxy resins, bisphenol F-type epoxy resins, bisphenol S-type epoxy resins, bixylenol-type epoxy resins and biphenol-type epoxy resins. Further, the bifunctional epoxy resin may be a hydrogenated bifunctional epoxy compound as well.

The above-described bifunctional epoxy resins of bisphenol-type or the like can be obtained by, for example, epoxidation of a bisphenol or a biphenol with epichlorohydrin or the like. Examples of the bisphenol include bisphenol A, bisphenol F, bis(4-hydroxyphenyl)menthane, bis(4-hydroxyphenyl)dicyclopentane, 4,4′-dihydroxybenzophenone, bis(4-hydroxyphenyl)ether, bis(4-hydroxy-3-methylphenyl)ether, bis(3,5-dimethyl-4-hydroxyphenyl)ether, bis(4-hydroxyphenyl)sulfide, bis(4-hydroxy-3-methylphenyl)sulfide, bis(3,5-dimethyl-4-hydroxyphenyl)sulfide, bis(4-hydroxyphenyl)sulfone, bis(4-hydroxy-3-methylphenyl)sulfone, bis(3,5-dimethyl-4-hydroxyphenyl)sulfone, 1,1-bis(4-hydroxyphenyl)cyclohexane, 1,1-bis(4-hydroxy-3-methylphenyl)cyclohexane, 1,1-bis(3,5-dimethyl-4-hydroxyphenyl)cyclohexane and 1,1′-bis(3-t-butyl-6-methyl-4-hydroxyphenyl)butane.

Examples of the hydrogenated bifunctional epoxy compound include hydrogenation products of: bisphenol A-type epoxy resins such as EPIKOTE 828, EPIKOTE 834, EPIKOTE 1001 and EPIKOTE 1004, which are manufactured by Mitsubishi Chemical Corporation, EPICLON 840, EPICLON 850, EPICLON 1050 and EPICLON 2055, which are manufactured by DIC Corporation, EPOTOHTO YD-011, YD-013, YD-127 and YD-128, which are manufactured by Tohto Kasei Co., Ltd., D.E.R.317, D.E.R.331, D.E.R.661 and D.E.R.664, which are manufactured by The Dow Chemical Company, ARALDITE 6071, ARALDITE 6084, ARALDITE GY250 and ARALDITE GY260, which are manufactured by BASF Japan Ltd., SUMI-EPDXY ESA-011, ESA-014, ELA-115 and ELA-128, which are manufactured by Sumitomo Chemical Co., Ltd., and A.E.R.330, A.E.R.331, A.E.R.661 and A.E.R.664, which are manufactured by Asahi Chemical Industry Co., Ltd. (all of the above are trade names); bisphenol F-type epoxy resins such as EPICLON 830 manufactured by DIC Corporation, EPIKOTE 807 manufactured by Mitsubishi Chemical Corporation, EPOTOHTO YDF-170, YDF-175 and YDF-2004, which are manufactured by Tohto Kasei Co., Ltd., ARALDITE XPY306 manufactured by BASF Japan Ltd. (all of the above are trade names); bixylenol-type or biphenol-type epoxy resins such as YL-6056, YX-4000 and YL-6121 (all of which are trade names), which are manufactured by Mitsubishi Chemical Corporation, and mixtures thereof; and bisphenol S-type epoxy resins such as EBPS-200 manufactured by Nippon Kayaku Co., Ltd., EPX-30 manufactured by ADEKA Corporation and EXA-1514 manufactured by DIC Corporation (all of the above are trade names). Among these, hydrogenated bisphenol A-type epoxy compounds are preferred and specific examples thereof include trade name “EPIKOTE YL-6663” manufactured by Mitsubishi Chemical Corporation; and trade names “EPOTOHTO ST-2004”, “EPOTOHTO ST-2007” and “EPOTOHTO ST-3000”, which are manufactured by Tohto Kasei Co., Ltd. Further, the hydrogenation rate of the epoxy compound is preferably 0.1% to 100% and a partially hydrogenated epoxy compound or a completely hydrogenated compound represented by the following Formula (1) can be employed.

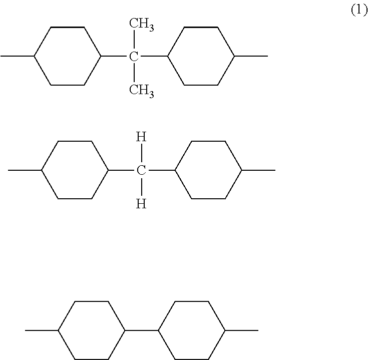

Examples of other liquid bifunctional epoxy resins include alicyclic epoxy resins such as vinylcyclohexene diepoxide, (3′,4′-epoxycyclohexylmethyl)-3,4-epoxycyclohexane carboxylate and (3′,4′-epoxy-6′-methylcyclohexylmethyl)-3,4-epoxy-6-methylcyclohexane carboxylate.

The above-described bifunctional epoxy resin has an epoxy equivalent of preferably 150 to 500, more preferably 170 to 300.

The content of the above-described epoxy resin is preferably 10 to 60 parts by mass, more preferably 20 to 50 parts by mass, with respect to 100 parts by mass of total carboxylic acid resins.

The above-described epoxy resins may be used individually, or two or more thereof may be used in combination.

Further, in addition to the epoxy resin, the photosensitive resin composition according to the present invention may also comprise, as required, a thermosetting component. Examples of the thermosetting component used in the present invention include those thermosetting resins that are known and commonly used, such as blocked isocyanate compounds, amino resins, maleimide compounds, benzoxazine resins, carbodiimide resins, cyclocarbonate compounds, multifunctional epoxy compounds, multifunctional oxetane compounds and episulfide resins. Preferred thereamong are those thermosetting components having a plurality of cyclic ether groups and/or cyclic thioether groups (hereinafter, simply referred to as “cyclic (thio)ether groups”) in one molecule. These thermosetting components having cyclic (thio)ether groups are commercially available in a number of types and are capable of imparting a variety of properties based on their structures.

Such thermosetting components having a plurality of cyclic (thio)ether groups in one molecule are compounds having two or more of either or both of 3-, 4- or 5-membered cyclic ether groups and cyclic thioether groups, and examples of such compounds include compounds having a plurality of oxetanyl groups in one molecule, that is, multifunctional oxetane compounds; and compounds having a plurality of thioether groups in one molecule, that is, episulfide resins.

(Compound having an Ethylenically Unsaturated Group (Photosensitive Monomer))

It is preferred that the photosensitive resin composition according to the present invention comprise a compound having one or more ethylenically unsaturated groups in the molecule (photosensitive monomer). Particularly, in cases where the photosensitive resin composition according to the present invention contains substantially no photosensitive carboxylic acid resin or contains only a small amount of the above-described photosensitive carboxylic acid resin, in order to impart the resin composition with sufficient photosensitivity, it is preferred that a large amount of photosensitive monomer be added.

Examples of compounds used as the above-described photosensitive monomer include those commonly used and known polyester (meth)acrylates, polyether (meth)acrylates, urethane (meth)acrylates, carbonate (meth)acrylates and epoxy (meth)acrylates. Specific examples thereof include hydroxyalkyl acrylates such as 2-hydroxyethylacrylate and 2-hydroxypropylacrylate; glycol diacrylates such as ethylene glycol, methoxytetraethylene glycol, polyethylene glycol and propylene glycol; acrylamides such as N,N-dimethylacrylamide, N-methylolacrylamide and N,N-dimethylaminopropylacrylamide; aminoalkylacrylates such as N,N-dimethylaminoethylacrylate and N,N-dimethylaminopropylacrylate; polyvalent acrylates of polyhydric alcohols (e.g. hexanediol, trimethylolpropane, pentaerythritol, dipentaerythritol and tris-hydroxyethyl isocyanurate) and ethylene oxide adducts, propylene oxide adducts or ε-caprolactone adducts of these polyhydric alcohols; polyvalent acrylates such as phenoxyacrylate, bisphenol A diacrylate and ethylene oxide adducts or propylene oxide adducts of these phenols; polyvalent acrylates of glycidyl ethers such as glycerin diglycidyl ether, glycerin triglycidyl ether, trimethylolpropane triglycidyl ether and triglycidyl isocyanate. In addition to these compounds, examples also include acrylates and melamine acrylates that are obtained by direct acrylation or diisocyanate-mediated urethane acrylation of a polyol such as polyether polyol, polycarbonate diol, hydroxyl group-terminated polybutadiene or polyester polyol; and methacrylates corresponding to the above-described acrylates.

Further, for example, an epoxy acrylate resin obtained by allowing a multifunctional epoxy resin such as a cresol novolac-type epoxy resin to react with acrylic acid or an epoxy urethane acrylate compound obtained by allowing the hydroxyl group of the above-described epoxy acrylate resin to react with a hydroxyacrylate such as pentaerythritol triacrylate and a half urethane compound of diisocyanate such as isophorone diisocyanate may also be employed as a photosensitive monomer. Such epoxy acrylate-based resins are capable of improving the photocuring property of the photosensitive resin composition without impairing the dryness to touch.

The content of the above-described compound having a plurality of ethylenically unsaturated groups in the molecule which is used as a photosensitive monomer is preferably 5 to 100 parts by mass, more preferably 5 to 70 parts by mass, with respect to 100 parts by mass of total carboxylic acid resins. When the above-described content is less than 5 parts by mass, the photocuring property of the photosensitive resin composition is impaired, so that it may become difficult form a pattern by development with an alkali after irradiation with an active energy beam. On the other hand, when the content is higher than 100 parts by mass, the dryness to touch (tack-free performance) as well as the resolution may be deteriorated.

### (Photosensitive Carboxylic Acid Resin)

It is preferred that the photosensitive resin composition according to the present invention comprise a photosensitive carboxylic acid resin.

The photosensitive carboxylic acid resin has, in addition to a carboxyl group, an ethylenically unsaturated bond in the molecule. As an ethylenically unsaturated double bond, one which is originated from acrylic acid, methacrylic acid or a derivative thereof is preferred.

Further, a photosensitive carboxylic acid resin in which an epoxy resin is not used as its starting material is also preferred. Such a carboxyl group-containing resin in which an epoxy resin is not used as its starting material contains very small amount of halide ion; therefore, the environmental effects and deterioration of the insulation reliability of the resulting cured film can be reduced.

Specific examples of photosensitive carboxylic acid resin that can be used in the photosensitive resin composition according to the present invention include the following compounds (that each may be either an oligomer or a polymer). Here, from the standpoint of reducing the environmental effects and deterioration of the insulation reliability of the resulting cured film, it is preferred that the amount of the photosensitive resin composition to be added be adjusted in such a manner that the amount of halogen is not increased.

(1) A photosensitive carboxylic acid resin obtained by copolymerization of an unsaturated carboxylic acid such as (meth)acrylic acid, an unsaturated group-containing compound such as styrene, α-methylstyrene, a lower alkyl (meth)acry late or isobutylene and the above-described photosensitive monomer.

(2) A photosensitive carboxylic acid resin having a (meth)acrylated terminal, which is obtained by adding a compound having one hydroxyl group and one or more (meth)acryloyl groups in the molecule, such as hydroxyalkyl (meth)acrylate, during the synthesis of a carboxyl group-containing urethane resin by a polyaddition reaction of a diisocyanate (e.g. an aliphatic diisocyanate, a branched aliphatic diisocyanate, an alicyclic diisocyanate or an aromatic diisocyanate), a carboxyl group-containing dialcohol compound (e.g. dimethylol propionic acid or dimethylol butanoic acid) and a diol compound (e.g. a polycarbonate-based polyol, a polyether-based polyol, a polyester-based polyol, a polyolefin-based polyol, an acrylic polyol, a bisphenol A-type alkylene oxide adduct diol or a compound having a phenolic hydroxyl group and an alcoholic hydroxyl group) (photosensitive carboxyl group-containing polyurethane resin).

(3) A photosensitive carboxylic acid resin having a (meth)acrylated terminal, which is obtained by adding a compound having one hydroxyl group and one or more (meth)acryloyl groups in the molecule, such as hydroxyalkyl (meth)acrylate, during the synthesis of a terminal carboxyl group-containing urethane resin where an acid anhydride is allowed to react with a terminal of a urethane resin by a polyaddition reaction of a diisocyanate compound (e.g. an aliphatic diisocyanate, a branched aliphatic diisocyanate, an alicyclic diisocyanate or an aromatic diisocyanate) and a diol compound (e.g. a polycarbonate-based polyol, a polyether-based polyol, a polyester-based polyol, a polyolefin-based polyol, an acrylic polyol, a bisphenol A-type alkylene oxide adduct diol or a compound having a phenolic hydroxyl group and an alcoholic hydroxyl group) (photosensitive carboxyl group-containing polyurethane resin).

(4) A photosensitive carboxylic acid resin obtained by a polyaddition reaction of a diisocyanate; a (meth)acrylate or a partial acid anhydride-modified product of a bifunctional epoxy resin such as a bisphenol A-type epoxy resin, a hydrogenated bisphenol A-type epoxy resin, a bisphenol F-type epoxy resin, a bisphenol S-type epoxy resin, a bixylenol-type epoxy resin or a biphenol-type epoxy resin; a carboxyl group-containing dialcohol compound; and a diol compound (photosensitive carboxyl group-containing polyurethane resin).

(5) A photosensitive carboxylic acid resin having a (meth)acrylated terminal, which is obtained by adding a compound having one hydroxyl group and one or more (meth)acryloyl groups in the molecule, such as hydroxyalkyl (meth)acrylate, during the synthesis of the resin described in the above (4) (photosensitive carboxyl group-containing polyurethane resin).

(6) A photosensitive carboxylic acid resin having a (meth)acrylated terminal, which is obtained by adding a compound having one isocyanate group and one or more (meth)acryloyl groups in the molecule, such as an equimolar reaction product of isophorone diisocyanate and pentaerythritol triacrylate, during the synthesis of the resin described in the above (2) or (4) (photosensitive carboxyl group-containing polyurethane resin).

(7) A photosensitive carboxylic acid resin in which a dibasic acid anhydride, such as a phthalic anhydride, a tetrahydrophthalic anhydride or a hexahydrophthalic anhydride, is added to a hydroxyl group present in the side chain by allowing the later-described multifunctional (solid) epoxy resin to react with (meth)acrylic acid.

(8) A photosensitive carboxyl group-containing resin prepared by allowing a multifunctional epoxy resin, which is obtained by further epoxidating a hydroxyl group of a bifunctional (solid) epoxy resin with epichlorohydrin, to react with (meth)acrylic acid and then adding a dibasic acid anhydride to the resulting hydroxyl group.

(9) A photosensitive carboxylic acid resin obtained by allowing the later-described bifunctional oxetane resin to react with a dicarboxylic acid and then adding a dibasic acid anhydride to the resulting primary hydroxyl group.

(10) A photosensitive carboxylic acid resin obtained by allowing a reaction product between a compound having a plurality of phenolic hydroxyl groups in one molecule and an alkylene oxide such as ethylene oxide or propylene oxide to react with an unsaturated group-containing monocarboxylic acid and then allowing the thus obtained reaction product to react with a polybasic acid anhydride.

(11) A photosensitive carboxylic acid resin obtained by allowing a reaction product between a compound having a plurality of phenolic hydroxyl groups in one molecule and a cyclic carbonate compound such as ethylene carbonate or propylene carbonate to react with an unsaturated group-containing monocarboxylic acid and then allowing the thus obtained reaction product to react with a polybasic acid anhydride.

(12) A photosensitive carboxylic acid resin obtained by allowing an epoxy compound having a plurality of epoxy groups in one molecule to react with a compound having at least one alcoholic hydroxyl group and one phenolic hydroxyl group in one molecule, such as p-hydroxyphenethyl alcohol, and an unsaturated group-containing monocarboxylic acid such as (meth)acrylic acid, and then allowing the alcoholic hydroxyl group(s) of the resulting reaction product to react with a polybasic acid anhydride such as a maleic anhydride, a tetrahydrophthalic anhydride, a trimellitic anhydride, a pyromellitic anhydride or adipic acid.

(13) A photosensitive carboxylic acid resin obtained by further adding a compound having one epoxy group and one or more (meth)acryloyl groups in the molecule, such as glycidyl (meth)acrylate or α-methylglycidyl (meth)acrylate, to any one of the resins according to the above (1) to (12).

Among the above-described photosensitive carboxylic acid resins, in a carboxyl group-containing urethane resin composed of a diisocyanate in which an isocyanate group of an isocyanate group-containing component (including diisocyanate) is not directly bound to a benzene ring, yellowing is inhibited, and such carboxyl group-containing urethane resin is effective for masking and absorbs only a small amount of UV ray; therefore, it is characterized by having excellent resolution and low warping property when made into an alkali developable composition.

It is noted here that “(meth)acrylate” is a general term for acrylates, methacrylates and mixtures thereof and this is hereinafter applicable to all similar expressions.

Since such photosensitive carboxylic acid resins described in the above have a number of carboxyl groups in the side chain of the backbone polymer, they can be developed with an aqueous alkaline solution.

Further, the above-described photosensitive carboxylic acid resin has an acid value in the range of preferably 20 to 200 mg KOH/g, more preferably 40 to 150 mg KOH/g. When the acid value of the photosensitive carboxylic acid resin is less than 20 mg KOH/g, a coating film having adhesion property may not be attained and development with an alkali may become difficult. On the other hand, when the acid value is higher than 200 mg KOH/g, since the developing solution further dissolves an exposed part, the resulting lines may become excessively thin and in some cases, the exposed and non-exposed parts may be indistinctively dissolved and detached by the developing solution, making it difficult to draw a normal resist pattern.

The weight-average molecular weight of the above-described photosensitive carboxylic acid resin varies depending on the resin skeleton; however, in general, it is preferably 2,000 to 150,000. When the weight-average molecular weight is less than 2,000, the tack-free performance may be poor and the moisture resistance of the resulting coating film after exposure may be deteriorated to cause a reduction in the film during development, which may greatly impair the resolution. On the other hand, when the weight-average molecular weight is greater than 150,000, the developing property may be markedly deteriorated and the storage stability may be impaired. The weight-average molecular weight of the photosensitive carboxylic acid resin is more preferably 5,000 to 100,000.

The content of the above-described photosensitive carboxylic acid resin is preferably not higher than 90 parts by mass, more preferably 50 to 80 parts by mass, with respect to 100 parts by mass of total carboxylic acid resins.

### (Photopolymerization Initiator)

It is preferred that the photosensitive resin composition according to the present invention comprise a photopolymerization initiator. As the photopolymerization initiator, any known photopolymerization initiator may be employed; however, preferred thereamong are oxime ester-based photopolymerization initiators having an oxime ester group, α-aminoacetophenone-based photopolymerization initiators and acylphosphine oxide-based photopolymerization initiators. These photopolymerization initiators may be used individually, or two or more thereof may be used in combination.

Examples of commercially available products of the oxime ester-based photopolymerization initiators include CGI-325, IRGACURE® OXE01 and IRGACURE OXE02, which are manufactured by BASF Japan Ltd.; and N-1919 and ADEKA ARKLS® NCI-831, which are manufactured by ADEKA Corporation.

Further, a photopolymerization initiator having two oxime ester groups in one molecule may also be suitably used and specific examples thereof include oxime ester compounds having a carbazole structure represented by the following Formula (2):

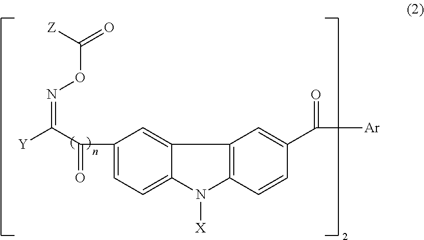

(wherein, X represents a hydrogen atom, an alkyl group having 1 to 17 carbon atoms, an alkoxy group having 1 to 8 carbon atoms, a phenyl group, a phenyl group (which is substituted by an alkyl group having 1 to 17 carbon atoms, an alkoxy group having 1 to 8 carbon atoms, an amino group, or an alkylamino group or dialkylamino group having an alkyl group of 1 to 8 carbon atoms) or a naphthyl group (which is substituted by an alkyl group having 1 to 17 carbon atoms, an alkoxy group having 1 to 8 carbon atoms, an amino group, or an alkylamino group or dialkylamino group having an alkyl group of 1 to 8 carbon atoms); Y and Z each independently represent a hydrogen atom, an alkyl group having 1 to 17 carbon atoms, an alkoxy group having 1 to 8 carbon atoms, a halogen group, a phenyl group, a phenyl group (which is substituted by an alkyl group having 1 to 17 carbon atoms, an alkoxy group having 1 to 8 carbon atoms, an amino group, or an alkylamino group or dialkylamino group having an alkyl group of 1 to 8 carbon atoms), a naphthyl group (which is substituted by an alkyl group having 1 to 17 carbon atoms, an alkoxy group having 1 to 8 carbon atoms, an amino group, or an alkylamino group or dialkylamino group having an alkyl group of 1 to 8 carbon atoms), an anthryl group, a pyridyl group, a benzofuryl group or a benzothienyl group; Ar represents an alkylene having 1 to 10 carbon atoms, a vinylene, a phenylene, a biphenylene, a pyridylene, a naphthylene, a thiophene, an anthrylene, a thienylene, a furylene, 2,5-pyrrole-diyl, 4,4′-stilbene-diyl or 4,2′-styrene-diyl; and n is an integer of 0 or 1).

Particularly, a preferred oxime ester-based photopolymerization initiator is one in which, in the above-described Formula, X and Y are each a methyl group or an ethyl group, Z is a methyl or a phenyl, n is 0 and Ar is a phenylene, a naphthylene, a thiophene or a thienylene.

In cases where an oxime ester-based photopolymerization initiator is used, the content thereof is preferably 0.01 to 5 parts by mass with respect to 100 parts by mass of total carboxylic acid resins. When the content is less than 0.01 parts by mass, the photocuring property on copper is insufficient, which may cause detachment of the resulting coating film and deteriorate the properties of the coating film such as chemical resistance. On the other hand, when the content is higher than 5 parts by mass, light absorption on the surface of solder resist coating film becomes intense, so that the curing property in the deep portion of the coating film tends to be impaired. The content of the oxime ester-based photopolymerization initiator is more preferably 0.5 to 3 parts by mass with respect to 100 parts by mass of total carboxylic acid resins.

Specific examples of the α-aminoacetophenone-based photopolymerization initiator include 2-methyl-1-[4-(methylthio)phenyl]-2-morpholinopropanone-1,2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-butanone and N,N-dimethylaminoacetophenone. Examples of commercially available α-aminoacetophenone-based photopolymerization initiator include IRGACURE 907, IRGACURE 369 and IRGACURE 379, which are manufactured by BASF Japan Ltd.

Specific examples of the acylphosphine oxide-based photopolymerization initiator include 2,4,6-trimethylbenzoyl diphenylphosphine oxide, bis(2,4,6-trimethylbenzoyl)-phenylphosphine oxide and bis(2,6-dimethoxybenzoyl)-2,4,4-trimethyl-pentylphosphine oxide. Examples of commercially available acylphosphine oxide-based photopolymerization initiator include LUCIRIN® TPO and IRGACURE 819, which are manufactured by BASF Japan Ltd.

In cases where an α-aminoacetophenone-based photopolymerization initiator or an acylphosphine oxide-based photopolymerization initiator is used, the content thereof is preferably 0.01 to 15 parts by mass with respect to 100 parts by mass of total carboxylic acid resins. When the content is less than 0.01 parts by mass, the photocuring property on copper is insufficient, which may cause detachment of the resulting coating film and deteriorate the properties of the coating film such as chemical resistance. On the other hand, when the content is higher than 15 parts by mass, sufficient outgas-reducing effect cannot be attained and light absorption on the surface of the resulting coating film becomes intense, so that the curing property in the deep portion of the coating film tends to be impaired. The content is more preferably 0.5 to 10 parts by mass with respect to 100 parts by mass of total carboxylic acid resins.

### (Photoinitiator Aid or Sensitizer)

In the photosensitive resin composition according to the present invention, in addition to the above-described photopolymerization initiator, a photoinitiator aid or a sensitizer can also be suitably used. Examples of the photoinitiator aid or the sensitizer include benzoin compounds, acetophenone compounds, anthraquinone compounds, thioxanthone compounds, ketal compounds, benzophenone compounds, tertiary amine compounds and xanthone compounds. These compounds may be used as a photopolymerization initiator in some cases; however, they are preferably used in combination with a photopolymerization initiator. Further, these photoinitiator aids or sensitizers may be used individually, or two or more thereof may be used in combination.

Examples of the benzoin compounds include benzoin, benzoin methyl ether, benzoin ethyl ether and benzoin isopropyl ether.

Examples of the acetophenone compounds include acetophenone, 2,2-dimethoxy-2-phenyl acetophenone, 2,2-diethoxy-2-phenyl acetophenone and 1,1-dichloroacetophenone.

Examples of the anthraquinone compounds include 2-methylanthraquinone, 2-ethylanthraquinone, 2-t-butylanthraquinone and 1-chloroanthraquinone.

Examples of the thioxanthone compounds include 2,4-dimethylthioxanthone, 2,4-diethylthioxanthone, 2-chlorothioxanthone and 2,4-diisopropylthioxanthone.

Examples of the ketal compounds include acetophenone dimethyl ketal and benzyldimethyl ketal.

Examples of the benzophenone compounds include benzophenone, 4-benzoyldiphenylsulfide, 4-benzoyl-4′-methyldiphenylsulfide, 4-benzoyl-4′-ethyldiphenylsulfide and 4-benzoyl-4′-propyldiphenylsulfide.

Examples of the tertiary amine compounds include ethanolamine compounds and compounds having a dialkylaminobenzene structure, and examples of commercially available products thereof include dialkylaminobenzophenones such as 4,4′-dimethylaminobenzophenone (NISSO CURE (registered trademark) MABP manufactured by Nippon Soda Co., Ltd.) and 4,4′-diethylaminobenzophenone (EAB manufactured by Hodogaya Chemical Co., Ltd.); dialkylamino group-containing coumarin compounds such as 7-(diethylamino)-4-methyl-2H-1-benzopyran-2-one (7-(diethylamino)-4-methylcoumarin); ethyl-4-dimethylaminobenzoate (KAYACURE® (registered trademark) EPA manufactured by Nippon Kayaku Co., Ltd.); ethyl-2-dimethylaminobenzoate (QUANTACURE DMB manufactured by International BioSynthetics Inc.); (n-butoxy)ethyl-4-dimethylaminobenzoate (QUANTACURE BEA manufactured by International BioSynthetics Inc.); isoamylethyl-p-dimethylaminobenzoate (KAYACURE DMBI manufactured by Nippon Kayaku Co., Ltd.); and 2-ethylhexyl-4-dimethylaminobenzoate (ESOLOL 507 manufactured by Van Dyk GmbH). Preferred tertiary amino compounds are those compounds having a dialkylaminobenzene structure and particularly preferred thereamong are dialkylaminobenzophenone compounds as well as dialkylamino group-containing coumarin compounds and ketocumarins that have the maximum absorption wavelength in the range of 350 to 450 nm.

As a dialkylaminobenzophenone compound, 4,4′-di ethylaminobenzophenone is preferred because of its low toxicity. Since a dialkylamino group-containing coumarin compound has the maximum absorption wavelength in the ultraviolet region of 350 to 410 nm, it causes little coloration, so that it becomes possible to obtain not only a colorless and transparent photosensitive composition, but also a colored solder resist film which exhibits the color of a coloring pigment itself when a coloring pigment is used. In particular, 7-(diethylamino)-4-methyl-2H-1-benzopyran-2-one is preferred since it exhibits excellent sensitization effect to a laserbeam having a wavelength of 400 to 410 nm.

Among the above-described compounds, thioxanthone compounds and tertiary amine compounds are preferred. In particular, by adding a thioxanthone compound, the curing property in the deep portion of the coating film can be improved.

In cases where a photoinitiator aid or a sensitizer is used, the content thereof is preferably 0.1 to 20 parts by mass with respect to 100 parts by mass of total carboxylic acid resins. When the content of the photoinitiator aid or the sensitizer is less than 0.1 parts by mass, sufficient sensitization effect tends not to be attained. On the other hand, when the content is higher than 20 parts by mass, light absorption by a tertiary amine compound on the surface of the coating film becomes intense, so that the curing property in the deep portion of the coating film tends to be impaired. The content of the photoinitiator aid or the sensitizer is more preferably 0.1 to 10 parts by mass with respect to 100 parts by mass of total carboxylic acid resins.

It is preferred that the total amount of the photopolymerization initiator, the photoinitiator aid and the sensitizer be not greater than 35 parts by mass with respect to 100 parts by mass of total carboxylic acid resins. When the amount is greater than 35 parts by mass, the curing property in the deep portion of the coating film tends to be impaired due to the light absorption by these components.

It is noted here that, since these photopolymerization initiator, photoinitiator aid and sensitizer absorb a light having a specific wavelength, they may reduce the sensitivity of the photosensitive resin composition in some cases and function as an UV absorber. However, these components are not used solely for the purpose of improving the sensitivity of the composition. These photopolymerization initiator, photoinitiator aid and sensitizer are, as required, capable of absorbing a light having a specific wavelength to change the line shape and opening of the resulting resist to a vertical-form, taper-form or reverse taper-form and improve the processing accuracy of the line width and opening size.

### (Chain Transfer Agent)

In the photosensitive resin composition according to the present invention, in order to improve the sensitivity thereof, a known and commonly used N-phenylglycine, phenoxyacetate, thiophenoxyacetate, mercaptothiazole or the like may be used as a chain transfer agent. Examples of the chain transfer agent include chain transfer agents having a carboxyl group, such as mercaptosuccinic acid, mercaptoacetic acid, mercaptopropionic acid, methionine, cysteine, thiosalicylic acid and derivatives thereof; chain transfer agents having a hydroxyl group, such as mercaptoethanol, mercaptopropanol, mercaptobutanol, mercaptopropanediol, mercaptobutanediol, hydroxybenzenethiol and derivatives thereof; 1-butanethiol; butyl-3-mercaptopropionate; methyl-3-mercaptopropionate; 2,2-(ethylenedioxy)diethanethiol; ethanethiol; 4-methylbenzenethiol; dodecylmercaptan; propanethiol; butanethiol; pentanethiol; 1-octanethiol; cyclopentanethiol; cyclohexanethiol; thioglycerol; and 4,4-thiobisbenzenethiol.

Further, as the chain transfer agent, a multifunctional mercaptan-based compound may also be employed. Examples of the multifunctional mercaptan-based compound include aliphatic thiols such as hexane-1,6-dithiol, decane-1,10-dithiol, dimercaptodiethyl ether and dimercaptodiethyl sulfide; aromatic thiols such as xylylene dimercaptan, 4,4′-dimercaptodiphenyl sulfide and 1,4-benzenedithiol; polymercaptoacetates of polyhydric alcohols, such as ethylene glycol bis(mercaptoacetate), polyethylene glycol bis(mercaptoacetate), propylene glycol bis(mercaptoacetate), glycerin tris(mercaptoacetate), trimethylolethane tris(mercaptoacetate), trimethylolpropane tris(mercaptoacetate), pentaerythritol tetrakis(mercaptoacetate) and dipentaerythritol hexakis(mercaptoacetate); poly-3-mercaptopropionates of polyhydric alcohols, such as ethylene glycol bis(3-mercaptopropionate), polyethylene glycol bis(3-mercaptopropionate), propylene glycol bis(3-mercaptopropionate), glycerin tris(3-mercaptopropionate), trimethylolethane tris(mercaptopropionate), trimethylolpropane tris(3-mercaptopropionate), pentaerythritol tetrakis(3-mercaptopropionate) and dipentaerythritol hexakis(3-mercaptopropionate); and polymercaptobutyrates such as 1,4-bis(3-mercaptobutyryloxy)butane, 1,3,5-tris(3-mercaptobutyloxyethyl)-1,3,5-triazine-2,4,6(1H,3H,5H)-trione and pentaerythritol tetrakis(3-mercaptobutyrate).

Examples of commercially available products of these chain transfer agents include BMPA, MPM, EHMP, NOMP, MBMP, STMP, TMMP, PEMP, DPMP and TEMPIC (all of which are manufactured by Sakai Chemical Industry Co., Ltd.); and KARENZ MT-PE1, KARENZ MT-BD1 and KARENZ NR1 (which are manufactured by Showa Denko K.K.).

Further, as the chain transfer agent, a heterocyclic compound having a mercapto group may also be employed. Examples of the heterocyclic compound having a mercapto group include mercapto-4-butyrolactone (synonym: 2-mercapto-4-butanolide), 2-mercapto-4-methyl-4-butyrolactone, 2-mercapto-4-ethyl-4-butyrolactone, 2-mercapto-4-butyrothiolactone, 2-mercapto-4-butyrolactam, N-methoxy-2-mercapto-4-butyrolactam, N-ethoxy-2-mercapto-4-butyrolactam, N-methyl-2-mercapto-4-butyrolactam, N-ethyl-2-mercapto-4-butyrolactam, N-(2-methoxy)ethyl-2-mercapto-4-butyrolactam, N-(2-ethoxy)ethyl-2-mercapto-4-butyrolactam, 2-mercapto-5-valerolactone, 2-mercapto-5-valerolactam, N-methyl-2-mercapto-5-valerolactam, N-ethyl-2-mercapto-5-valerolactam, N-(2-methoxy)ethyl-2-mercapto-5-valerolactam, N-(2-ethoxy)ethyl-2-mercapto-5-valerolactam, 2-mercaptobenzothiazole, 2-mercapto-5-methylthio-thiadiazole, 2-mercapto-6-hexanolactam, 2,4,6-trimercapto-s-triazine (manufactured by Sankyo Kasei Co., Ltd.: trade name “ZISNET F”), 2-dibutylamino-4,6-dimercapto-s-triazine (manufactured by Sankyo Kasei Co., Ltd.: trade name “ZISNET DB”) and 2-anilino-4,6-dimercapto-s-triazine (manufactured by Sankyo Kasei Co., Ltd.: trade name “ZISNET AF”).

Particularly, mercaptobenzothiazole, 3-mercapto-4-methyl-4H-1,2,4-triazole, 5-methyl-1,3,4-thiadiazole-2-thiol and 1-phenyl-5-mercapto-1H-tetrazole are preferred since these do not impair the developing property of the photosensitive resin composition. These chain transfer agents may be used individually, or two or more thereof may be used in combination.

### (Compound Having Isocyanate Groups or Blocked Isocyanate Groups)

Further, in the photosensitive resin composition according to the present invention, in order to improve the curing property thereof and the toughness of the resulting cured film, a compound having a plurality of isocyanate groups or blocked isocyanate groups in one molecule may be added. Examples thereof include compounds having a plurality of isocyanate groups in one molecule, that is, polyisocyanate compounds; and compounds having a plurality of blocked isocyanate groups in one molecule, that is, blocked isocyanate compounds.

As the above-described polyisocyanate compound, for example, an aromatic polyisocyanate, an aliphatic polyisocyanate or an alicyclic polyisocyanate may be employed. Specific examples of the aromatic polyisocyanate include 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate and 2,4-tolylene dimer. Specific examples of the aliphatic polyisocyanate include tetramethylene diisocyanate, hexamethylene diisocyanate, methylene diisocyanate, trimethylhexamethylene diisocyanate, 4,4-methylene bis(cyclohexylisocyanate) and isophorone diisocyanate. Specific examples of the alicyclic polyisocyanate include bicycloheptane triisocyanate. Further, examples of the above-described polyisocyanate compound also include adducts, biurets and isocyanurates of the above-described isocyanate compounds.

The blocked isocyanate groups contained in the blocked isocyanate compound are groups in which isocyanate groups are protected and thus temporarily inactivated by a reaction with a blocking agent. When the blocked isocyanate compound is heated to a prescribed temperature, the blocking agent is dissociated to yield isocyanate groups.

As the blocked isocyanate compound, a product of an addition reaction between an isocyanate compound and an isocyanate blocking agent is employed. Examples of an isocyanate compound which can undergo reaction with a blocking agent include isocyanurate-type, biuret-type and adduct-type isocyanate compounds. As this isocyanate compound, for example, an aromatic polyisocyanate, an aliphatic polyisocyanate or an alicyclic polyisocyanate is used. Specific examples thereof include those compounds that are exemplified in the above.

Examples of the isocyanate blocking agent include phenolic blocking agents such as phenol, cresol, xylenol, chlorophenol and ethylphenol; lactam-based blocking agents such as ε-caprolactam, δ-valerolactam, γ-butyrolactam and β-propiolactam; activated methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate and ethyl lactate; oxime-based blocking agents such as formaldehyde oxime, acetaldoxime, acetoxime, methyl ethyl ketoxime, diacetyl monooxime and cyclohexane oxime; mercaptan-based blocking agents such as butylmercaptan, hexylmercaptan, t-butylmercaptan, thiophenol, methylthiophenol and ethylthiophenol; acid amid-based blocking agents such as acetic acid amide and benzamide; imide-based blocking agents such as succinic acid imide and maleic acid imide; amine-based blocking agents such as xylidine, aniline, butylamine and dibutylamine; imidazole-based blocking agents such as imidazole and 2-ethylimidazole; and imine-based blocking agents such as methyleneimine and propyleneimine.

The blocked isocyanate compound may be a commercially available product and examples thereof include SUMIDUR BL-3175, BL-4165, BL-1100 and BL-1265, DESMODUR TPLS-2957, TPLS-2062, TPLS-2078 and TPLS-2117, and DESMOTHERM 2170 and 2265 (all of which are manufactured by Sumitomo Bayer Urethane Co., Ltd.; trade names); CORONATE 2512, CORONATE 2513 and CORONATE 2520 (all of which are Nippon Polyurethane Industry Co., Ltd.; trade names); B-830, B-815, B-846, B-870, B-874 and B-882 (all of which are manufactured by Mitsui Takeda Chemicals Inc.; trade names); and TPA-B80E, 17B-60PX and E402-B80T (all of which are manufactured by Asahi Kasei Chemicals Corporation; trade names). It is noted here that SUMIDUR BL-3175 and BL-4265 are produced by using methylethyl oxime as a blocking agent.

The above-described compounds having a plurality of isocyanate groups or blocked isocyanate groups in one molecule may be used individually, or two or more thereof may be used in combination.

The content of such compound(s) having a plurality of isocyanate groups or blocked isocyanate groups in one molecule is 1 to 100 parts by mass, more preferably 2 to 70 parts by mass, with respect to 100 parts by mass of total carboxylic acid resins. When the content is less than 1 part by mass, a coating film having sufficient toughness may not be obtained. On the other hand, when the content is higher than 100 parts by mass, the storage stability may be reduced.

### (Urethanation Catalyst)

In the photosensitive resin composition according to the present invention, in order to facilitate the curing reaction between a hydroxyl group or a carboxyl group and an isocyanate group, a urethanation catalyst may be added. It is preferred that at least one urethanation catalyst selected from the group consisting of tin-based catalysts, metal chlorides, metal acetylacetates, metal sulfates, amine compounds and amine salts be used.

Examples of the above-described tin-based catalysts include organic and inorganic tin compounds such as stannous octoate and dibutyltin dilaurate.

Examples of the above-described metal chlorides include those composed of Cr, Mn, Co, Ni, Fe, Cu or Al, such as cobalt (II) chloride, nickelous chloride and ferric chloride.

Examples of the above-described metal acetylacetonates include those composed of Cr, Mn, Co, Ni, Fe, Cu or Al, such as cobalt acetylacetonate, nickel acetylacetonate and iron acetylacetonate.

Examples of the above-described metal sulfates include those composed of Cr, Mn, Co, Ni, Fe, Cu or Al, such as copper sulfate.

Examples of the above-described amine compounds include triethylenediamine, N,N,N,N′-tetramethyl-1,6-hexanediamine, bis(2-dimethylaminoethyl)ether, N,N,N′,N″,N″-pentamethyl diethylenetriamine, N-methylmorpholine, N-ethylmorpholine, N,N-dimethylethanolamine, dimorpholinodiethyl ether, N-methylimidazole, dimethylaminopyridine, triazine, N-(2-hydroxyethyl)-N,N,N′-trimethyl-bis(2-aminoethyl)ether, N,N-dimethylhexanolamine, N,N-dimethylaminoethoxy ethanol, N,N,N-trimethyl-N′-(2-hydroxyethyl)ethylenediamine, N-(2-hydroxyethyl)-N,N,N″,N″-tetramethyl diethylenetriamine, N-(2-hydroxypropyl)-N,N′,N″,N″-tetramethyl diethylenetriamine, N,N,N′-trimethyl-N′-(2-hydroxyethyl)propanediamine, N-methyl-N′-(2-hydroxyethyl)piperazine, bis(N,N-dimethylaminopropyl)amine, bis(N,N-dimethylaminopropyl)isopropanolamine, 2-aminoquinuclidine, 3-aminoquinuclidine, 4-aminoquinuclidine, 2-quinuclidinol, 3-quinuclidinol, 4-quinuclidinol, 1-(2′-hydroxypropyl)imidazole, 1-(2′-hydroxypropyl)-2-methylimidazole, 1-(2′-hydroxyethyl)imidazole, 1-(2′-hydroxyethyl)-2-methyl imidazole, 1-(2′-hydroxypropyl)-2-methylimidazole, 1-(3′-aminopropyl)imidazole, 1-(3′-aminopropyl)-2-methylimidazole, 1-(3′-hydroxypropyl)imidazole, 1-(3′-hydroxypropyl)-2-methylimidazole, N,N-dimethylaminopropyl-N′-(2-hydroxyethyl)amine, N,N-dimethylaminopropyl-N′,N′-bis(2-hydroxyethyl)amine, N,N-dimethylaminopropyl-N′,N′-bis(2-hydroxypropyl)amine, N,N-dimethylaminoethyl-N′, N-bis(2-hydroxyethyl)amine, N,N-dimethylaminoethyl-N′, N′-bis(2-hydroxypropyl)amine, melamine and benzoguanamine, all of which are conventionally known.

Examples of the above-described amine salts include organic acid-based amine salts of DBU (1,8-diaza-bicyclo[5.4.0]undecene-7).

The content of the above-described urethanation catalyst is preferably 0.1 to 20 parts by mass, more preferably 0.5 to 10.0 parts by mass, with respect to 100 parts by mass of total carboxylic acid resins.

### (Thermosetting Component)

In the photosensitive resin composition according to the present invention, a thermosetting component, for example, an amino resin such as a melamine derivative or a benzoguanamine derivative may be used. Examples of such thermosetting component include methylol melamine compounds, methylol benzoguanamine compounds, methylol glycoluril compounds, methylol urea compounds, alkoxymethylated melamine compounds, alkoxymethylated benzoguanamine compounds, alkoxymethylated glycoluril compound and alkoxymethylated urea compounds. The type of the alkoxymethyl group of the above-described compounds is not particularly restricted and examples thereof include a methoxymethyl group, an ethoxymethyl group, a propoxymethyl group and a butoxymethyl group. Particularly, a melamine derivative having a formalin concentration of not higher than 0.2%, which is not harmful to human body and environment. The above-described thermosetting components may be used individually, or two or more thereof may be used in combination.

Examples of commercially available products of the above-described thermosetting components include CYMEL 300, 301, 303, 370, 325, 327, 701, 266, 267, 238, 1141, 272, 202, 1156, 1158, 1123, 1170, 1174, UFR65 and 300 (all of which are manufactured by Mitsui Cyanamid Co., Ltd.); and NIKALAC Mx-750, Mx-032, Mx-270, Mx-280, Mx-290, Mx-706, Mx-708, Mx-40, Mx-31, Ms-11, Mw-30, Mw-30HM, Mw-390, Mw-100LM and Mw-750LM (all of which are manufactured by Sanwa Chemical Co., Ltd.).

### (Thermosetting Catalyst)

In cases where a thermosetting component having a plurality of cyclic (thio)ether groups in the molecule is used, it is preferred that the photosensitive resin composition according to the present invention comprise a thermosetting catalyst. Examples of the thermosetting catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine and 4-methyl-N,N-dimethylbenzylamine; hydrazine compounds such as adipic acid dihydrazide and sebacic acid dihydrazide; and phosphorus compounds such as triphenylphosphine. Further, examples of commercially available thermosetting catalyst include 2MZ-A, 2MZ-OK, 2PHZ, 2P4BHZ and 2P4 MHZ (all of which are imidazole-based compounds; trade names), which are manufactured by Shikoku Chemicals Corporation; and U-CAT (registered trademark) 3503N and U-CAT 3502T (both of which are blocked isocyanate compounds of dimethylamine; trade names) and DBU, DBN, U-CATSA102 and U-CAT5002 (which are bicyclic amidine compounds or salts thereof), which are manufactured by San-Apro Ltd. The thermosetting catalyst is not particularly restricted to these and it may be a thermosetting catalyst of an epoxy resin or an oxetane compound, or any compound which facilitates the reaction of an epoxy group and/or an oxetanyl group with a carboxyl group. These thermosetting catalysts may be used individually, or two or more thereof may be used in combination. Further, a S-triazine derivative, such as guanamine, acetoguanamine, benzoguanamine, melamine, 2,4-diamino-6-methacryloyloxyethyl-5-triazine, 2-vinyl-2,4-diamino-5-triazine, 2-vinyl-4,6-diamino-5-triazine isocyanuric acid adduct or 2,4-diamino-6-methacryloyloxyethyl-5-triazine isocyanuric acid adduct, may also be used. Preferably, such a compound which also functions as an adhesion-imparting agent is used in combination with the above-described thermosetting catalyst.

The content of the thermosetting catalyst(s) is preferably 0.1 to 20 parts by mass, more preferably 0.5 to 15.0 parts by mass, with respect to 100 parts by mass of total carboxylic acid resins.

### (Adhesion Promoting Agent)

In the photosensitive resin composition according to the present invention, an adhesion promoting agent may be used in order to improve the interlayer adhesion or adhesion between a photosensitive resin layer and a substrate. Examples of the adhesion promoting agent include benzoimidazole, benzoxazole, benzothiazole, 2-mercaptobenzoimidazole, 2-mercaptobenzoxazole, 2-mercaptobenzothiazole (trade name: ACCEL M; manufactured by Kawaguchi Chemical Industry Co., Ltd.), 3-morpholinomethyl-1-phenyl-triazole-2-thione, 5-amino-3-morpholinomethyl-thiazole-2-thi one, 2-mercapto-5-methylthio-thiadiazole, triazole, tetrazole, benzotriazole, carboxybenzotriazole, amino group-containing benzotriazole and silane coupling agents.

### (Colorant)

The photosensitive resin composition according to the present invention may also comprise a colorant. As the colorant, for example, a commonly used and known red, blue, green, yellow or white colorant may be employed and it may be any of a pigment, a stain or a dye. Specific examples of the colorant include those assigned with the following Color Index numbers (C.I.; issued by The Society of Dyers and Colourists). Here, from the standpoints of the masking property and heat resistance, it is preferred to add a green colorant containing a halogen, such as chlorinated phthalocyanine green.

Red Colorant:

Examples of red colorant include monoazo-type, disazo-type, azo lake-type, benzimidazolone-type, perylene-type, diketopyrrolopyrrole-type, condensed azo-type, anthraquinone-type and quinacridone-type red colorants and specific examples thereof include the followings.

Monoazo-type: Pigment Red 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268 and 269.

Disazo-type: Pigment Red 37, 38 and 41.

Monoazo lake-type: Pigment Red 48:1, 48:2, 48:3, 48:4, 49:1, 49:2, 50:1, 52:1, 52:2, 53:1, 53:2, 57:1, 58:4, 63:1, 63:2, 64:1 and 68.

Benzimidazolone-type: Pigment Red 171, Pigment Red 175, Pigment Red 176, Pigment Red 185 and Pigment Red 208.

Perylene-type: Solvent Red 135, Solvent Red 179, Pigment Red 123, Pigment Red 149, Pigment Red 166, Pigment Red 178, Pigment Red 179, Pigment Red 190, Pigment Red 194 and Pigment Red 224.

Diketopyrrolopyrrole-type: Pigment Red 254, Pigment Red 255, Pigment Red 264, Pigment Red 270 and Pigment Red 272.

Condensed azo-type: Pigment Red 220, Pigment Red 144, Pigment Red 166, Pigment Red 214, Pigment Red 220, Pigment Red 221 and Pigment Red 242.

Anthraquinone-type: Pigment Red 168, Pigment Red 177, Pigment Red 216, Solvent Red 149, Solvent Red 150, Solvent Red 52 and Solvent Red 207.

Quinacridone-type: Pigment Red 122, Pigment Red 202, Pigment Red 206, Pigment Red 207 and Pigment Red 209.

Blue Colorant:

Examples of blue colorant include phthalocyanine-type and anthraquinone-type blue colorants and examples of pigment-type blue colorant include those compounds that are classified into pigment. Specific examples include Pigment Blue 15, Pigment Blue 15:1, Pigment Blue 15:2, Pigment Blue 15:3, Pigment Blue 15:4, Pigment Blue 15:6, Pigment Blue 16 and Pigment Blue 60.

As a stain-type blue colorant, for example, Solvent Blue 35, Solvent Blue 63, Solvent Blue 68, Solvent Blue 70, Solvent Blue 83, Solvent Blue 87, Solvent Blue 94, Solvent Blue 97, Solvent Blue 122, Solvent Blue 136, Solvent Blue 67 and Solvent Blue 70 can be used. In addition to the above-described ones, a metal-substituted or unsubstituted phthalocyanine compound can be used as well.

Green Colorant:

In the same manner, examples of green colorant include phthalocyanine-type, anthraquinone-type and perylene-type green colorants and specifically, for example, Pigment Green 7, Pigment Green 36, Solvent Green 3, Solvent Green 5, Solvent Green 20 and Solvent Green 28 can be used. In addition to the above-described ones, a metal-substituted or unsubstituted phthalocyanine compound can be used as well.

Yellow Colorant:

Examples of yellow colorant include monoazo-type, disazo-type, condensed azo-type, benzimidazolone-type, isoindolinone-type and anthraquinone-type yellow colorants and specific examples thereof include the followings.

Anthraquinone-type: Solvent Yellow 163, Pigment Yellow 24, Pigment Yellow 108, Pigment Yellow 193, Pigment Yellow 147, Pigment Yellow 199 and Pigment Yellow 202.

Isoindolinone-type: Pigment Yellow 110, Pigment Yellow 109, Pigment Yellow 139, Pigment Yellow 179 and Pigment Yellow 185.

Condensed azo-type: Pigment Yellow 93, Pigment Yellow 94, Pigment Yellow 95, Pigment Yellow 128, Pigment Yellow 155, Pigment Yellow 166 and Pigment Yellow 180.

Benzimidazolone-type: Pigment Yellow 120, Pigment Yellow 151, Pigment Yellow 154, Pigment Yellow 156, Pigment Yellow 175 and Pigment Yellow 181.

Monoazo-type: Pigment Yellow 1, 2, 3, 4, 5, 6, 9, 10, 12, 61, 62, 62:1, 65, 73, 74, 75, 97, 100, 104, 105, 111, 116, 167, 168, 169, 182 and 183.

Disazo-type: Pigment Yellow 12, 13, 14, 16, 17, 55, 63, 81, 83, 87, 126, 127, 152, 170, 172, 174, 176, 188 and 198.

In addition to the above, for example, a violet, orange, brown or black colorant may also be added in order to adjust the color tone.

Specific examples thereof include Pigment Violet 19, 23, 29, 32, 36, 38 and 42, Solvent Violet 13 and 36, C.I. Pigment Orange 1, C.I. Pigment Orange 5, C.I. Pigment Orange 13, C.I. Pigment Orange 14, C.I. Pigment Orange 16, C.I. Pigment Orange 17, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 51, C.I. Pigment Orange 61, C.I. Pigment Orange 63, C.I. Pigment Orange 64, C.I. Pigment Orange 71, C.I. Pigment Orange 73, C.I. Pigment Brown 23, C.I. Pigment Brown 25, C.I. Pigment Black 1 and C.I. Pigment Black 7.

The content of the colorant is not particularly restricted; however, it is preferably 0.01 to 10 parts by mass, particularly preferably 0.1 to 5 parts by mass, with respect to 100 parts by mass of the above-described total carboxylic acid resins.

### (Organic Solvent)

Further, the photosensitive resin composition according to the present invention may also comprise an organic solvent for the purpose of synthesizing the above-described non-photosensitive carboxylic acid resin, preparing the composition or adjusting the viscosity for coating onto a substrate or a carrier film.

Examples of such an organic solvent include ketones, aromatic hydrocarbons, glycol ethers, glycol ether acetates, esters, alcohols, aliphatic hydrocarbons and petroleum-based solvents. More specific examples thereof include ketones such as methyl ethyl ketone and cyclohexanone; aromatic hydrocarbons such as toluene, xylene and tetramethylbenzene; glycol ethers such as cellosolve, methylcellosolve, butylcellosolve, carbitol, methylcarbitol, butylcarbitol, propylene glycol monomethyl ether, dipropylene glycol monomethyl ether, dipropylene glycol diethyl ether and triethylene glycol monoethyl ether; esters such as ethyl acetate, butyl acetate, dipropylene glycol methyl ether acetate, propylene glycol methyl ether acetate, propylene glycol ethyl ether acetate and propylene glycol butyl ether acetate; alcohols such as ethanol, propanol, ethylene glycol and propylene glycol; aliphatic hydrocarbons such as octane and decane; and petroleum-based solvents such as petroleum ether, petroleum naphtha, hydrogenated petroleum naphtha and solvent naphtha. These organic solvents may be used individually, or two or more thereof may be used in combination.

### (Antioxidant)

The photosensitive resin composition according to the present invention may also comprise, in order to inhibit oxidation thereof, an antioxidant such as a radical scavenger which deactivates generated radicals or a peroxide decomposer which decomposes generated peroxide into a non-toxic substance and prevents generation of new radicals. The antioxidant used in the preset invention is capable of inhibiting oxidative degradation and yellowing of a resin and the like. Further, by adding such an antioxidant, in addition to these effects, for example, halation caused by photocuring reaction of the photosensitive resin composition can be prevented and the opening shape can be stabilized, so that it becomes possible to improve the process margin for the preparation of the photosensitive resin composition. Such antioxidant may be used individually, or two or more thereof may be used in combination.

Examples of the antioxidant which functions as a radical scavenger include phenolic compounds such as hydroquinone, 4-t-butylcatechol, 2-t-butylhydroquinone, hydroquinone monomethyl ether, 2,6-di-t-butyl-p-cresol, 2,2-methylene-bis(4-methyl-6-t-butylphenol), 1,1,3-tris(2-methyl-4-hydroxy-5-t-butylphenyl)butane, 1,3,5-trimethyl-2,4,6-tris(3,5-di-t-butyl-4-hydroxybenzyl)benzene and 1,3,5-tris(3′,5′-di-t-butyl-4-hydroxybenzyl)-S-triazine-2,4,6-(1H,3H,5H)trione; quinone-based compounds such as metaquinone and benzoquinone; and amine-based compounds such as bis(2,2,6,6-tetramethyl-4-piperidyl)-sebacate and phenothiazine. Examples of commercially available products of these compounds include ADEKA STAB AO-30, ADEKA STAB AO-330, ADEKA STAB AO-20, ADEKA STAB LA-77, ADEKA STAB LA-57, ADEKA STAB LA-67, ADEKA STAB LA-68 and ADEKA STAB LA-87 (all of which are manufactured by ADEKA Corporation, trade names); and IRGANOX 1010, IRGANOX 1035, IRGANOX 1076, IRGANOX 1135, TINUVIN 111FDL, TINUVIN 123, TINUVIN 144, TINUVIN 152, TINUVIN 292 and TINUVIN 5100 (all of which are manufactured by Ciba Specialty Chemicals Inc., trade names).

Examples of the antioxidant functioning as a peroxide decomposer include phosphorus-based compounds such as triphenylphosphite and sulfur-based compounds such as pentaerythritol tetralauryl thiopropionate, dilauryl thiodipropionate and distearyl-3,3′-thiodipropionate. Examples of commercially available products of these compounds include ADEKA STAB TPP (manufactured by ADEKA Corporation; trade name), MARK AO-412S (manufactured by Adeka Argus Chemical Co., Ltd.; trade name) and SUMILIZER TPS (manufactured by Sumitomo Chemical Co., Ltd.; trade name).

In cases where the above-described antioxidant is used, the content thereof is preferably 0.01 to 10 parts by mass, more preferably 0.01 to 5 parts by mass, with respect to 100 parts by mass of total carboxylic acid resins. When the content of the antioxidant is less than 0.01 parts by mass, the above-described effects of adding the antioxidant may not be attained. On the other hand, when the antioxidant is blended in a large amount of more than 10 parts by mass, there are risks that photoreaction is inhibited, development with an aqueous alkaline solution becomes defective, the tack property is deteriorated and the physical properties of the resulting coating film are impaired; therefore, such a large amount of the antioxidant is not preferred.

Further, since an additional effect may be exhibited by using the above-described antioxidant, particularly a phenolic antioxidant, in combination with a heat resistance stabilizer, a heat resistance stabilizer may also be added to the photosensitive resin composition according to the present invention.

Examples of the heat resistance stabilizer include phosphorus-based, hydroxylamine-based and sulfur-based heat resistance stabilizers. Examples of commercially available products of these heat resistance stabilizers include IRGAFOX 168, IRGAFOX 12, IRGAFOX 38, IRGASTAB PUR 68, IRGASTAB PVC76, IRGASTAB FS301FF, IRGASTAB FS110, IRGASTAB FS210FF, IRGASTAB FS410FF, IRGANOX PS800FD, IRGANOX PS802FD, RECYCLOSTAB 411, RECYCLOSTAB 451AR, RECYCLOSSORB 550 and RECYCLOBLEND 660 (all of which are manufactured by BASF Japan Ltd.; trade names). The above-described heat resistance stabilizers may be used individually, or two or more thereof may be used in combination.

In cases where a heat resistance stabilizer is used, the content thereof is preferably 0.01 to 10 parts by mass, more preferably 0.01 to 5 parts by mass, with respect to 100 parts by mass of total carboxylic acid resins.

### (UV Absorber)

Since polymeric materials generally absorb light and are thereby degraded and deteriorated, in the photosensitive resin composition according to the present invention, for stabilization thereof against UV rays, an UV absorber may be used in addition to the above-described antioxidant.

Examples of the UV absorber include benzophenone derivatives, benzoate derivatives, benzotriazole derivatives, triazine derivatives, benzothiazole derivatives, cinnamate derivatives, anthranilate derivatives and dibenzoylmethane derivatives. Specific examples of the benzophenone derivatives include 2-hydroxy-4-methoxybenzophenone, 2-hydroxy-4-n-octoxybenzophenone, 2,2′-dihydroxy-4-methoxybenzophenone and 2,4-dihydroxybenzophenone. Specific examples of the benzoate derivatives include 2-ethylhexylsalicylate, phenylsalicylate, p-t-butylphenylsalicylate, 2,4-di-t-butylphenyl-3,5-di-t-butyl-4-hydroxybenzoate and hexadecyl-3,5-di-t-butyl-4-hydroxybenzoate. Specific examples of the benzotriazole derivatives include 2-(2′-hydroxy-5′-t-butylphenyl)benzotriazole, 2-(2′-hydroxy-5′-methylphenyl)benzotriazole, 2-(2′-hydroxy-3′-t-butyl-5′-methylphenyl)-5-chlorobenzotriazole, 2-(2′-hydroxy-3′,5′-di-t-butylphenyl)-5-chlorobenzotriazole, 2-(2′-hydroxy-5′-methylphenyl)benzotriazole and 2-(2′-hydroxy-3′,5′-di-t-amylphenyl)benzotriazole. Specific examples of the triazine derivatives include hydroxyphenyltriazine and bis-ethylhexyloxyphenol methoxyphenyl triazine.

Examples of commercially available UV absorber include TINUVIN PS, TINUVIN 99-2, TINUVIN 109, TINUVIN 384-2, TINUVIN 900, TINUVIN 928, TINUVIN 1130, TINUVIN 400, TINUVIN 405, TINUVIN 460 and TINUVIN 479 (all of which are manufactured by BASF Japan Ltd.; trade names).

The above-described UV absorbers may be used individually, or two or more thereof may be used in combination. By using the UV absorber(s) in combination with the above-described antioxidant, a cured product obtained from the photosensitive resin composition according to the present invention can be stabilized.

### (Additives)

The photosensitive resin composition according to the present invention may further comprise, as required, a thixo agent such as fine powder silica, organic bentonite, montmorillonite or hydrotalcite. As the thixo agent, organic bentonite and hydrotalcite are preferred because of their excellent stability with time and hydrotalcite is particularly preferred since it has excellent electrical characteristics. In addition, an additive(s) that are known and commonly used, such as a thermal polymerization inhibitor, a silicone-based, fluorine-based or polymer-based antifoaming agent, a leveling agent, a corrosion inhibitor and/or a bisphenol-based or triazinethiol-based copper inhibitor, may also be added.

The above-described thermal polymerization inhibitor can be used to inhibit thermal polymerization or polymerization with time of the above-described polymerizable compound. Examples of the thermal polymerization inhibitor include 4-methoxyphenol, hydroquinone, alkyl- or aryl-substituted hydroquinone, t-butylcatechol, pyrogallol, 2-hydroxybenzophenone, 4-methoxy-2-hydroxybenzophenone, cuprous chloride, phenothiazine, chloranil, naphthylamine, f3-naphthol, 2,6-di-t-butyl-4-cresol, 2,2′-methylenebis(4-methyl-6-t-butylphenol), pyridine, nitrobenzene, dinitrobenzene, picric acid, 4-toluidine, methylene blue, a reaction product between copper and an organic chelating agent, methyl salicylate and a chelate between phenothiazine, a nitroso compound or a nitroso compound and Al.

The photosensitive resin composition according to the present invention is, for example, after being adjusted with the above-described organic solvent to have a viscosity suitable for a coating method, applied onto a substrate by a dip coating method, a flow coating method, a roll coating method, a bar coater method, a screen printing method, a curtain coating method or the like and then heated at a temperature of about 60 to 100° C. to dry the organic solvent contained in the composition by evaporation (predrying), thereby a tack-free coating film can be formed. Further, in cases where the above-described composition is coated and dried on a carrier film and the resulting film is then rolled up to obtain a dry film, a resin insulation layer can be formed by pasting the dry film onto a substrate using a laminator or the like such that the photosensitive resin composition layer and the substrate are in contact with each other and then removing the carrier film.

Thereafter, a resist pattern is formed by selectively exposing the resultant to an active energy beam through a patterned photomask by a contact (or non-contact) method or directly exposing the resultant to a pattern using a laser direct exposure apparatus, and then developing the resulting non-exposed part with a dilute aqueous alkaline solution (for example, 0.3 to 3 wt % aqueous sodium carbonate solution). Further, in cases where the composition comprises a thermosetting component, for example, by heating the composition to a temperature of about 140 to 180° C. to thermally cure the composition, the carboxyl group of the above-described carboxylic acid resin undergoes reaction with the thermosetting component, thereby a cured coating film having a variety of excellent properties such as heat resistance, chemical resistance, moisture resistance, adhesion property and electrical properties can be formed. Here, even when the composition contains no thermosetting component, by subjecting the composition to a heat treatment, the ethylenically unsaturated bonds remaining unreacted at the time of exposure undergo thermal radical polymerization and the properties of the resulting coating film are thereby improved; therefore, a heat treatment (thermal curing) may also be performed depending on the purpose and application of the film.

Examples of the above-described substrate include, in addition to printed wiring boards and flexible printed wiring boards in which a circuit is formed in advance, copper-clad laminates of all grades (for example, FR-4), for example, copper-clad laminates for high-frequency circuit that are composed of a material such as paper phenol, paper epoxy, glass fabric epoxy, glass polyimide, glass fabric/nonwoven epoxy, glass fabric/paper epoxy, synthetic fiber epoxy or fluorine-polyethylene-PPO-cyanate ester; polyimide films; PET films; glass substrates; ceramic substrates; and wafer plates.

The drying of the photosensitive resin composition according to the present invention by evaporation, which is done after applying the composition onto a substrate, can be carried out using a hot air circulation-type drying oven, an IR oven, a hot plate, a convection oven or the like (a method in which a dryer equipped with a heat source utilizing a steam air-heating system is employed to bring a hot air inside the dryer into contact against the composition or a method in which a hot air is blown against the substrate via a nozzle).

After applying the photosensitive resin composition and drying the solvent by evaporation, the resulting coating film is exposed to a light (irradiated with an active energy beam), thereby the exposed area (those parts irradiated with the active energy beam) is cured.

The exposure apparatus used for the above-described irradiation with an active energy beam may be any apparatus equipped with a high-pressure mercury lamp, an ultra-high-pressure mercury lamp, a metal halide lamp, a mercury short arc lamp or the like by which an ultraviolet ray is irradiated in the range of 350 to 450 nm. Further, a direct imaging apparatus (for example, a laser direct imaging apparatus which utilizes a laser to directly draw an image based on CAD data from a computer) can be used as well. The laser source of the direct imaging apparatus may either be a gas laser or a solid-state laser as long as the laser beam has a maximum wavelength in the range of 350 to 410 nm. The exposure dose for image formation varies depending on the film thickness and the like; however, in general, it may be in the range of 20 to 800 mJ/cm², preferably 20 to 600 mJ/cm².

The above-described development can be performed by, for example, a dipping method, a shower method, a spray method or a brush method. As a developing solution, an aqueous alkaline solution of potassium hydroxide, sodium hydroxide, sodium carbonate, potassium carbonate, sodium phosphate, sodium silicate, ammonia, amine or the like can be employed.

### EXAMPLES

The present invention will now be described more concretely by way of examples and comparative examples thereof; however, the present invention is not restricted thereto. It is noted here that, unless otherwise specified, “parts” and “%” are hereinafter all based on mass.

### <Synthesis of Non-photosensitive Carboxylic Acid Resin>

In a 2,000-ml flask equipped with a stirrer and a condenser tube, 431 g of dipropylene glycol monomethyl ether was placed and heated to 90° C. under nitrogen gas flow.

Then, 104.2 g of styrene, 296.6 g of methacrylic acid, 23.9 g of dimethyl-2,2′-azobis(2-methylpropionate) (manufactured by Wako Pure Chemical Industries, Ltd.: V-601) were mixed and dissolved and the resultant was added dropwise to the flask over a period of 4 hours.

In this manner, a non-photosensitive carboxylic acid resin A was obtained. This A has a solid acid value of 140 mg KOH/g and a solid content of 50%. (Preparation of Photosensitive Resin Compositions of Examples 1 to 6 and Comparative Examples 1 to 5)

The compounds shown in Table 1 below were blended at the respective ratios (parts by mass) shown in Table 1. The resultants were each pre-mixed using a stirrer and then kneaded using a three-roll mill to prepare photosensitive resin compositions.

TABLE 1

| | Example | | | | | | Comparative Example | | | | |
|---|---|---|---|---|---|---|---|---|---|---|---|
| | 1 | 2 | 3 | 4 | 5 | 6 | 1 | 2 | 3 | 4 | 5 |
| Non-photosensitive | 100(50) | 100(50) | 100(50) | 100(50) | 160(80) | 40(20) | 100(50) | 100(50) | 100(50) | 0 | 0 |
| carboxylic acid resin A *1 | | | | | | | | | | | |
| Kaolin *2 | 250 | 250 | 0 | 200 | 250 | 250 | 0 | 0 | 0 | 0 | 250 |
| SILLITIN *3 | 0 | 0 | 250 | 0 | 0 | 0 | 0 | 0 | 0 | 0 | 0 |
| Aluminum hydroxide *4 | 0 | 0 | 0 | 50 | 0 | 0 | 0 | 0 | 0 | 0 | 0 |
| Barium sulfate | 0 | 0 | 0 | 0 | 0 | 0 | 150 | 0 | 0 | 150 | 0 |
| Silica | 0 | 0 | 0 | 0 | 0 | 0 | 0 | 250 | 0 | 0 | 0 |
| Talc | 0 | 0 | 0 | 0 | 0 | 0 | 0 | 0 | 250 | 0 | 0 |
| 828 *5 | 40 | 20 | 20 | 20 | 20 | 20 | 20 | 20 | 20 | 0 | 20 |
| N-695 *6 | 0 | 20 | 20 | 20 | 20 | 20 | 20 | 20 | 20 | 40 | 20 |
| M-350 *7 | 50 | 30 | 30 | 30 | 30 | 30 | 30 | 30 | 30 | 30 | 30 |
| R-2000 *8 | 77(50) | 77(50) | 77(50) | 77(50) | 31(20) | 123(80) | 77(50) | 77(50) | 77(50) | 154(100) | 154(100) |
| Organic pigment *9 | 2 | 2 | 2 | 2 | | 2 | 2 | 2 | 2 | 2 | 2 |
| IRGACURE 907 *10 | 15 | 15 | 15 | 15 | 15 | 15 | 15 | 15 | 15 | 15 | 15 |
| DETX-S *11 | 1 | 1 | 1 | 1 | 1 | 1 | 1 | 1 | 1 | 1 | 1 |
| DICY *12 | 1 | 1 | 1 | 1 | 1 | 1 | 1 | 1 | 1 | 1 | 1 |
| Melamine | 5 | 5 | 5 | 5 | 5 | 5 | 5 | 5 | 5 | 5 | 5 |
| KS-66 *13 | 3 | 3 | 3 | 3 | 3 | 3 | 3 | 3 | 3 | 3 | 3 |
| DPM *14 | 36 | 36 | 36 | 36 | 36 | 36 | 36 | 36 | 36 | 36 | 36 |

*1 The non-photosensitive carboxylic acid resin A synthesized in the above. The numbers in parentheses indicate the solid content values.
*2 Kaolin; KAOFINE 90 (manufactured by Shiraishi Calcium Kaisha, Ltd.)
*3 SILLITIN; SILLITIN P87 (manufactured by Hoffmann Mineral GmbH)
*4 Aluminum hydroxide; HIGILITE H-42M (manufactured by Showa Denko K.K.)
*5 828; liquid bifunctional epoxy resin, EPIKOTE 828 (manufactured by Mitsubishi Chemical Corporation)
*6 N-695; novolac-type epoxy resin, EPICLON N-695 (manufactured by DIC Corporation)
*7 M-350; acrylic acid ester of ethylene oxide-modified trimethylolpropane (manufactured by Toagosei Co., Ltd.)
*8 R-2000; photosensitive carboxylic acid resin, UNIDIC R-2000 (solid content: 65%) (manufactured by DIC Corporation)
The numbers in parentheses indicate the solid content values.
*9 Organic pigment; Pigment Blue 15:3 + Pigment Green 7 + Pigment Yellow 147 = 1:1:2
*10 IRGACURE 907; α-aminoacetophenone-based photopolymerization initiator (manufactured by BASF Japan Ltd.)
*11 DETX-S; 2,4-diethylthioxanthone (manufactured by Nippon Kayaku Co., Ltd.)
*12 DICY; dicyandiamide
*13 KS-66; silicone-based antifoaming agent (manufactured by Shin-Etsu Chemical Co., Ltd.)
*14 DPM; dipropylene glycol monomethyl ether acetate

### (Evaluation Methods)

The photosensitive resin compositions of Examples and Comparative Examples were each applied onto the entire surface of a patterned copper foil substrate by screen printing to a dry film thickness of 20 μm. The resultants were dried at 80° C. for 30 minutes and then allowed to cool to room temperature. Using an exposure apparatus equipped with a high-pressure mercury lamp, each of the thus obtained substrates was exposed to a pattern at an optimum exposure dose and then developed with 1 wt % aqueous sodium carbonate solution at 30° C. for 60 seconds at a spray pressure of 0.2 MPa to form a pattern.

The resulting substrates were each subjected to post-curing at 150° C. for 60 minutes to prepare evaluation substrates on which a cured-product pattern was formed.

The thus obtained evaluation substrates were used to evaluate the following properties in the manner described below.

### <Solder Heat Resistance>

After the above-described post-curing at 150° C. for 60 minutes, the thus obtained substrates were each coated with a water-soluble flux (W-2704, manufactured by MEC Co., Ltd.) and immersed in a 288° C. solder bath for 15 seconds. Then, the resulting substrates were placed in water of about 60° C. and left to stand for 10 minutes (flux removing step). The substrates were taken out of water and water remaining on the substrate surface was carefully wiped off.

Using the thus obtained evaluation substrates, the presence/absence of detachment of the resist layer was evaluated by a tape peeling test. The evaluation criteria were as follows. The results are shown in Table 2 below.

©: After two immersions of 30 seconds each, no detachment was observed at all.

◯: After an immersion of 30 seconds, no detachment was observed.

X: After an immersion of 30 seconds, the resist layer was swollen and detached.

### <Resistance to Electroless Gold Plating>

The evaluation substrates were each plated in a commercially available electroless nickel plating bath and electroless gold plating bath at a temperature of 80 to 90° C. to a nickel thickness of 5 μm and a gold thickness of 0.05 μm. For the thus plated evaluation substrates, after visually evaluating the presence/absence of infiltration of the plating solution, the presence/absence of detachment of the resist layer was evaluated by a tape peeling test. The evaluation criteria were as follows. The results are shown in Table 2 below.

©: No infiltration was observed at all after the plating and the resist layer was not detached after the tape peeling test.

◯: A slight infiltration was observed after the plating, but the resist layer was not detached after the tape peeling test.

Δ: A slight infiltration was observed after the plating and the resist layer was slightly detached after the tape peeling test.

X: Infiltration was observed after the plating and the resist layer was detached after the tape peeling test.

### <Whitening of Plating, Whitening of Leveler>

After the above-described evaluations of the resistance to electroless gold plating and the solder heat resistance, the condition of the cloudiness on the cured film surface was visually evaluated. The evaluation criteria were as follows. The results are shown in Table 2 below.

⊚: No color change was observed in the cured film at all.

∘: A slight color change was observed in the cured film, but it did not present any issue for the outer appearance.

Δ: The cured film was partially clouded in white.

X: The entire cured film was clouded in white.

### <Halogen Amount>

A cured film sample was prepared by an ordinary process. This sample was subjected to a combustion treatment at 900° C. and the generated gas was collected in a hydrogen peroxide solution. The solution after the gas collection was qualitatively and quantitatively analyzed by ion chromatography.

TABLE 2

| | Example | | | | | | Comparative Example | | | | |
|---|---|---|---|---|---|---|---|---|---|---|---|
| | 1 | 2 | 3 | 4 | 5 | 6 | 1 | 2 | 3 | 4 | 5 |
| Resistance | ⊚ | ○ | ○ | ○ | ○ | ○ | ○ | ○ | ○ | ○ | ○ |
| to | | | | | | | | | | | |
| electroless | | | | | | | | | | | |
| gold plating | | | | | | | | | | | |
| Solder heat | ○ | ○ | ○ | ○ | ○ | ○ | ○ | ○ | ○ | ⊚ | ○ |
| resistance | | | | | | | | | | | |
| Whitening: | ⊚ | ⊚ | ⊚ | ⊚ | ○ | ⊚ | Δ | x | x | ○ | ○ |
| whitening | | | | | | | | | | | |
| of plating | | | | | | | | | | | |
| Whitening: | ⊚ | ○ | ○ | ○ | ○ | ⊚ | x | x | x | x | x |
| whitening | | | | | | | | | | | |
| of leveler | | | | | | | | | | | |
| Halogen | 730 | 633 | 633 | 638 | 520 | 850 | 850 | 724 | 724 | 1153 | 950 |
| amount | | | | | | | | | | | |
| Specific | 1.43 | 1.43 | 1.43 | 1.43 | 1.43 | 1.42 | 1.40 | 1.41 | 1.45 | 1.42 | 1.45 |
| gravity | | | | | | | | | | | |

As seen from Table 2, in Comparative Examples 1, 2 and 3 where no aluminum-containing filler was used, it was confirmed that the cured films became clouded in white in both of the plating whitening test and the leveler whitening test. Also, in Comparative Example 4 where no non-photosensitive carboxylic acid resin was used, it was confirmed that the cured film became clouded in white in the leveler whitening test performed under stringent conditions. In contrast to these results, no color change was observed in the cured films and good results were obtained in all of Examples where an aluminum-containing filler was used.

In addition, in Comparative Examples 4 and 5 where a photosensitive carboxylic acid resin of an epoxy resin origin was solely used without any non-photosensitive carboxylic acid resin in the total carboxylic acid resins, the chlorine content was not lower than 900 ppm, so that it was confirmed that a large amount of halogen was contained therein. In contrast to this, in all of Examples where a non-photosensitive carboxylic acid resin was used in combination with the above-described photosensitive carboxylic acid resin, the chlorine content was not higher than 900 ppm, so that it was confirmed that the amount of halogen contained therein was small.

1. A photosensitive resin composition, comprising
(A) a non-photosensitive carboxylic acid resin,
(B) an aluminum-containing inorganic filler, and
(C) an epoxy resin.

2. The photosensitive resin composition according to claim 1, which further comprises a photosensitive monomer.

3. The photosensitive resin composition according to claim 1, wherein said (C) epoxy resin is a bifunctional epoxy resin.

4. The photosensitive resin composition according to claim 1, which further comprises a photosensitive carboxylic acid resin.

5. The photosensitive resin composition according to claim 2, which further comprises a photosensitive carboxylic acid resin.

6. The photosensitive resin composition according to claim 1, which has a chlorine content of not higher than 900 ppm.

7. The photosensitive resin composition according to claim 1, which is a solder resist.

8. A cured film, which is obtained by curing the photosensitive resin composition according to claim 1.

9. A printed circuit board, comprising the cured film according to claim 7.
